(19) United States
(12) Patent Application Publication
(10) Pub. No.: US 2021/0183812 A1
(43) Pub. Date: Jun. 17, 2021

(54) SYSTEM AND METHOD FOR SAFE MULTILEVEL CHIPS

(71) Applicant: Vathys, Inc., Portland, OR (US)

(72) Inventor: Tapabrata Ghosh, Portland, OR (US)

(21) Appl. No.: 16/712,834

(22) Filed: Dec. 12, 2019

(51) Int. Cl. H01L 25/065; H01L 23/473; H01L 25/00

(52) U.S. Cl. CPC H01L 25/0652; H01L 23/4735; H01L 2225/06589; H01L 2225/06541; H01L 25/50

(57) ABSTRACT

Three-dimensional and multilayered integrated circuits have emerged as desirable structures to increase computational power and density of modern computers, including those tasked with performing artificial intelligence workloads. Various functional compute systems can be vertically-integrated to provide higher bandwidth and locality of data. For example, a processor layer on top of a memory layer can perform memory reads and writes faster than two-dimensional systems. Additionally, the vertically-integrated systems can provide higher density computing resources per unit of volume, compared to two-dimensional systems. However, vertical integration impedes access to intermediate layers for thermal management. Disclosed are systems and methods which can provide thermal safety for three-dimensional and multilayered integrated circuits, including intermediate layers by using vertical cooling channels.

### BACKGROUND

### Field

This invention relates generally to the field of three-dimensional integrated circuits, and more particularly to thermal management of three-dimensional integrated circuits.

### Description of the Related Art

Recent demand for higher computing power in smaller packages has spurred the development of more dense computing systems that integrated more transistors, chips and other integrated circuit (IC) components in smaller form factors. Packing more compute units in smaller form factors can mean that these dense computing systems generate more heat per unit of area or volume, compared to the systems that came before them. Several modern solutions have provided efficient thermal management for dense computing systems, including heat sinks, immersion cooling and microfluidic cooling.

At the same time, vertical integration of integrated circuits and three-dimensional computing systems has emerged as another popular technology for building more compute units per unit area or volume. Many traditional and modern thermal management solutions have mostly been developed for two-dimensional integrated circuits, which have dominated the field until now. In two-dimensional computing systems, access to a top or bottom surface area of chips allows traditional or modern thermal management solutions to remove heat efficiently. By vertical stacking of integrated circuits, heat generating surface areas can be buried and inaccessible between multiple layers. While some traditional cooling mechanisms can be deployed in the three-dimensional integrated circuits (ICs), their inclusion is not without technical challenges, such as adding substantial thickness to the vertically-integrated device, thereby canceling out of some of the advantages of the vertical integration. Consequently, improved thermal management solutions for three-dimensional and vertically-integrated computing systems are needed.

### SUMMARY

In one respect, a system is disclosed. The system includes: a first substrate comprising a first plurality of chiplets and a first plurality of interconnects connecting two or more of the first plurality of chiplets, wherein the first substrate comprises a top surface; a second substrate comprising a second plurality of chiplets and a second plurality of interconnects connecting two or more of the second plurality of chiplets, wherein the second substrate comprises a bottom surface, and wherein the first and second substrates are vertically stacked; a plurality of through silicon vias (TSVs), connecting one or more of the first plurality of chiplets from the first substrate to one or more of the second plurality of the chiplets from the second substrate, wherein the first and second vertically-stacked substrates comprise an active volume comprising the chiplets, the interconnects and the TSVs, and remaining volume of the vertically-stacked first and second substrates comprise an inactive volume; and a plurality of vertical cooling channels, formed in the inactive volume and extending from the top surface of the first substrate to the bottom surface of the second substrate.

In one embodiment, the chiplets comprise one or more of processor chips, memory chips, logic chips, and sensor chips.

In some embodiments, the system, further includes a tank of single-phase dielectric coolant, wherein the vertically-stacked first and second substrates are immersed in the single-phase dielectric coolant.

In one embodiment, the system further includes a pump introducing velocity to the single-phase dielectric coolant entering the plurality of the vertical cooling channels.

In another embodiment, the system further includes a tank of two-phase dielectric coolant, wherein the vertically-stacked first and second substrates are immersed in the two-phase dielectric coolant.

In some embodiments, the system, further includes a pump introducing velocity to the two-phase dielectric coolant entering the vertical cooling channels.

In one embodiment, the system further includes a top microfluidic substrate disposed on the top surface of the first substrate and a bottom microfluidic substrate disposed on the bottom surface of the second substrate, and wherein the top and bottom microfluidic substrates comprise complementary channels connecting two or more vertical cooling channels.

In another embodiment, the system further includes a cap substrate, wherein the cap substrate comprises a network of nozzles configured to spray a coolant into the vertical cooling channels.

In another embodiment, the active and inactive volumes are chosen such that the vertical cooling channels diffuse a heat flux density of greater than 1 kWatts/cm2.

In some embodiments, the vertical cooling channels are formed via laser micro-drilling, etching or a combination of the two.

In another respect, a method is disclosed. The method includes the steps of: forming, on a first substrate, a first plurality of chiplets and a first plurality of interconnects connecting two or more of the first plurality of chiplets, wherein the first substrate comprises a top surface; forming, on a second substrate, a second plurality of chiplets and a second plurality of interconnects connecting two or more of the second plurality of chiplets, wherein the second substrate comprises a bottom surface; vertically stacking the first and the second substrates; connecting one or more of the first plurality of chiplets from the first substrate to one or more of the second plurality of the chiplets from the second substrate via a plurality of through silicon vias (TSVs), wherein the first and second vertically-stacked substrates comprise an active volume comprising the chiplets, the interconnects and the TSVs, and remaining volume of the vertically-stacked first and second substrates comprise an inactive volume; and forming a plurality of vertical cooling channels in the inactive volume, wherein the vertical cooling channels extend from the top surface of the first substrate to the bottom surface of the second substrate.

In some embodiments, the chiplets comprise one or more of processor chips, memory chips, logic chips, and sensor chips.

In another embodiment, the method further includes immersing the vertically-stacked first and second substrates in a tank of single-phase dielectric coolant.

In some embodiments, the method further includes pumping the single-phase dielectric coolant through one or more of the plurality of the vertical cooling channels.

In one embodiment, the method further includes immersing the vertically-stacked first and second substrates in a tank of two-phase dielectric coolant.

In another embodiment, the method further includes pumping the two-phase dielectric coolant through one or more of the plurality of the vertical cooling channels.

In one embodiment, the method further includes: forming a top microfluidic substrate on the top surface of the first substrate; and forming a bottom microfluidic substrate on the bottom surface of the second substrate, wherein the top and bottom microfluidic substrates comprise complementary channels connecting two or more vertical cooling channels.

In another embodiment, the method further includes forming a cap substrate, wherein the cap substrate comprises a network of nozzles configured to spray a coolant into the vertical cooling channels.

In some embodiments, the active and inactive volumes are chosen such that the vertical cooling channels diffuse a heat flux density of greater than 1 kWatts/cm2.

In one embodiment, forming the vertical cooling channels comprises laser micro-drilling, etching or a combination of the two.

### BRIEF DESCRIPTION OF THE DRAWINGS

These drawings and the associated description herein are provided to illustrate specific embodiments of the invention and are not intended to be limiting.

FIG. 1 illustrates an example three-dimensional integrated circuit.

FIG. 2 illustrates a substrate from the three-dimensional integrated circuit of FIG. 1 retrofitted with microfluidic cooling channels.

FIG. 3 illustrates a multilayered integrated circuit, which includes vertical cooling channels that utilize chip surface areas for cooling channels.

FIG. 4A and 4B illustrate various immersion cooling techniques that can be employed in combination with the vertical cooling channels to provide thermal management for the multilayered integrated circuit of FIG. 3.

FIG. 4C illustrates a diagram of active single-phase or two-phase immersion cooling, which in combination with vertical cooling channels, can provide thermal management to the multilayered integrated circuit of FIG. 3.

FIG. 5 illustrates a microfluidic cooling system, which can be deployed with vertical cooling channels to provide thermal management for the multilayered integrated circuit of FIG. 3.

FIG. 6 illustrates a thermal solution system, utilizing spray cooling or impingement cooling in combination with vertical cooling channels.

### DETAILED DESCRIPTION

The following detailed description of certain embodiments presents various descriptions of specific embodiments of the invention. However, the invention can be embodied in a multitude of different ways as defined and covered by the claims. In this description, reference is made to the drawings where like reference numerals may indicate identical or functionally similar elements.

Unless defined otherwise, all terms used herein have the same meaning as are commonly understood by one of skill in the art to which this invention belongs. All patents, patent applications and publications referred to throughout the disclosure herein are incorporated by reference in their entirety. In the event that there is a plurality of definitions for a term herein, those in this section prevail. When the terms “one”, “a” or “an” are used in the disclosure, they mean “at least one” or “one or more”, unless otherwise indicated.

### Definitions

“Heat flux density” or “thermal flux density” is a measure of the flow of energy per unit of area, per unit of time, having units of Watts per square meters or centimeters in SI.

“Through-silicon via” or “TSV” is a vertical electrical connection (via) that passes completely through a silicon wafer or die to connect components on vertically-stacked silicon substrates.

### Vertically-Integrated Computing Systems

The continuous demand for increased computing power in smaller packages has resulted in computing architectures that integrate more processing power density in smaller packages. One such modern architecture is three-dimensional (3D) integrated circuits (ICs). 3D ICs integrate various electrical components in multiple layers in the vertical direction, stacked on top of one another. Techniques, such as through-silicon vias (TSVs) can be used to create electrical connections between the various layers, and build a vertically-integrated computing system. For example, one or more layers can be memory arrays and one or more layers can be various processing layers, which access the memory arrays to read input and to write output values.

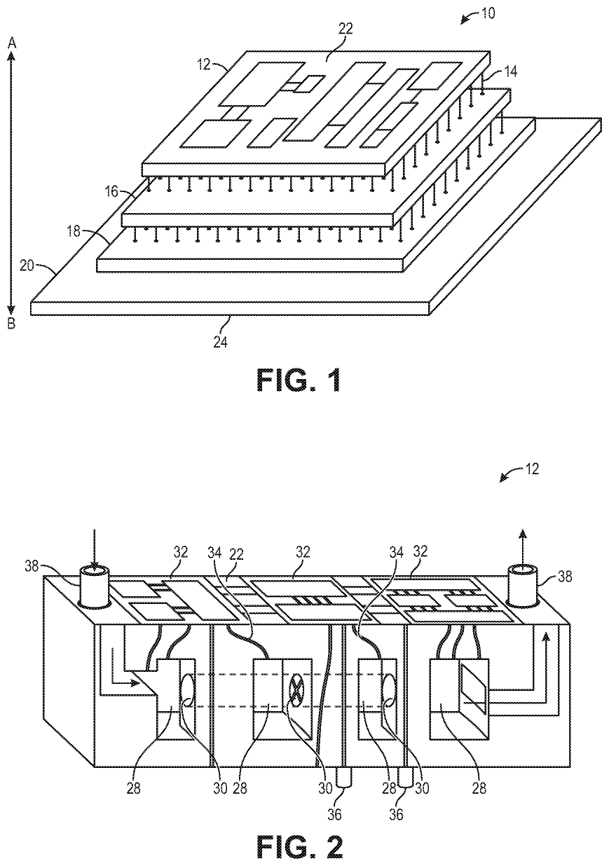

FIG. 1 illustrates an example 3D IC 10. In one example, the 3D IC 10 can include various layers and substrates, such as substrates 12, 16 and 18, arranged on top of one another in the vertical direction A-B, atop a substrate 20. Each substrate 12, 16 and 18 can include various chips, circuits, chiplets, dies, wafer-scale integrated (WSI) systems, interconnects, power delivery buses, wires, micro-electro-mechanical systems (MEMS), sensors or other micro-electro, mechanical components, depending on the implementation and intended application of the 3D IC 10. For example, layer 12 can be a sensor layer intended to interface with a physical environment to measure a physical parameter, while layer 16 may be a memory layer and layer 18 may be a processor layer. In another example, of 3D IC 10, layers 12 and 16 may both be memory layers, while layer 18 can include the processors that interface with memory layers 12 and 16 to implement computing functionality. The components from one substrate can be connected to components in another substrate by way of through-silicon vias (TSVs) 14. TSVs can run straight down in the vertical direction A-B or can be designed to comprise a route connecting two components that may be offset from one another relative to the vertical direction A-B. The components in one layer can be connected to components in another layer by other wired or wireless methods as well. Other connection methods can include, capacitive coupling, inductive coupling, flip chip, wire bond, package-on-package methods or any other methods of connecting stacks of chips arranged in the vertical direction.

In vertical three-dimensional integration of ICs, the top and bottom surface areas of the intermediate substrates are used to mechanically support and extend the IC and its functionality in the vertical direction. This can present challenges for power delivery and thermal management solutions that traditionally have relied on those surfaces to implement their solutions. For example, in two-dimensional (2D) systems, heat sinks can be installed or fabricated on the top surface area of the 2D chip to provide cooling. The 2D chip also can be immersed in a tank of dielectric coolant, where heat transferred from the surface area of the 2D chip to the dielectric coolant can cool the 2D chip. However, stacking ICs vertically can make some or a substantial portion of those surfaces unavailable, and thus alternative cooling solutions are needed to address the loss of surface area to the vertical integration.

### Thermal Management Via High-Heat Flux Cooling

To provide thermal management to the 3D IC 10, one solution is to add a heat sink of higher capacity to the 3D IC 10 using the surface areas that are accessible. For example, the top surface of the top substrate 12, surface 22, and/or the bottom surface of the bottom substrate 20, surface 24, can be used to add one or more heat sink thermal management solutions to the 3D IC 10. An increased-capacity heat sink can be added to the 3D IC 10 and a linearly-summed heat flux density calculation can be used to arrive at the desired heat diffusion capacity of the heat sink. For example, if the 3D IC 10 includes 8 substrates or layers of heat flux density of approximately 40 Watts/cm², then a heat sink with capacity of diffusing 320 Watts/cm² can be added to the accessible top or bottom surfaces 22 and 24 of the 3D IC 10. Other alternative thermal solutions, such as jet impingement cooling, one or two-phase immersion cooling can also be used if they can be implemented to remove heat at the heat flux density of approximately 320 Watts/cm² from the 3D IC 10.

However, the thermal challenges of the 3D IC 10 can be more nuanced in some implementation, where the thermal flux density of the 3D IC 10 may not linearly increase as a function of the number of substrates or layers used therein. For example, the intermediate layers, such as substrate 16 and its embedded electronics, have no direct thermal path to the heat extracting medium or heat extracting surfaces. While thermal vias can help improve the situation, for many high-density 3D computing systems, the inability to efficiently remove heat from the intermediate layers or substrates can present a challenge. “Thermal via” can refer to a micro-hole formed underneath or around a heat generating element through its substrate and preferably to a heat extracting surface. Thermal vias can provide a passive pathway for removal of heat from a heat generating element. In the case of dense computing systems, the thickness and heat removal capacity of thermal vias alone may not be enough to prevent thermal runaway and destructive high temperature situations. Additionally, cooler operating temperatures in general can allow for more performant ICs. Consequently, thermal vias may have to be used with other thermal management solutions, such as heat sinks, fluid cooling, immersion cooling techniques, or other cooling techniques, described herein.

### Thermal Management Via Microfluidic Cooling

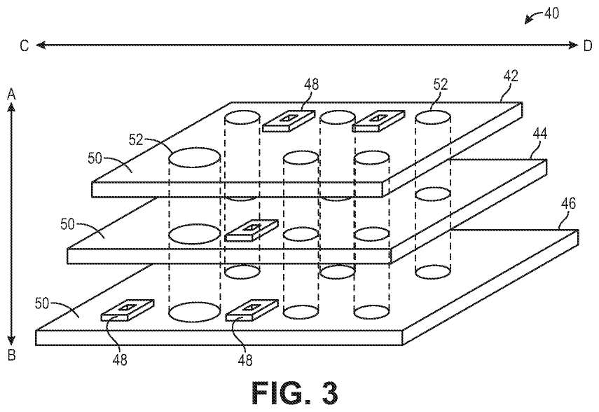

Heat management for the 3D IC 10 can also be provided by integrating microfluidic channels between the layers of the 3D IC 10. Microfluidics can include circulating very small volumes of coolants, such as fluids or gasses (e.g., as small as femtoliters) through miniaturized channels, chambers and tunnels, which can extract heat from the layers of the 3D IC 10. FIG. 2 illustrates substrate 12 from the 3D IC 10 retrofitted with microfluidic cooling chambers 28. The thickness of the substrate 12 can be increased to accommodate the microfluidic chambers 28. The substrate 12 can include one or more chips 32, embedded in or on the surface 22. Additionally, the substrate 12 can include thermal vias 34. The thermal vias 34 are holes in the substrate 12 to help spread away or remove heat away from the chips 32. The chips 32 can include any heat generating elements, including chips, circuits, dies, assembled, mounted or fabricated components that may be present in a computing system. The chips 32 can be connected to the chips on other layers of the 3D IC 10 via one or more electrical vias 36, and/or via other interlayer connection methodologies. Coolant fluids or gases are injected into and extracted from the microfluidic chambers 28 via inlet/outlet ports 38. Microvalves 30 can connect the microfluidic chambers 28 to allow for movement of the coolant between and/or through the inlet/outlet ports 38 and the microfluidic chambers 28.

Microfluidic cooling for two-dimensional chips has shown success, handling heat fluxes as high as approximately 1 kWatts/cm². However, their integration in three-dimensional computing structures is not without challenges. For example, the added thickness of the microfluidic chambers (whether as separate layers or as part of a substrate, as shown in FIG. 2) can be undesirable in some three-dimensional ICs. In many vertically-integrated systems, a layer thickness, or substrate thickness in the order of a few nanometers is desirable, while microfluidic chambers, at minimum, can add approximately 30-50 micrometers to the thickness of a substrate or a dedicated microfluidic cooling channel. In some cases, the microfluidic chambers 28 have to be of a thickness greater than a thickness tolerance threshold, in order to manage the fluidic pressure requirements within the chambers. Pressure drop in a microfluidic chamber can have a nonlinear relationship with the diameter of the chamber and/or the effective volume of a network of the microfluidic chambers. Excessive pressure drop in the microfluidic channels can require high-power pumps and input pressures, which can be inefficient and lead to mechanical issues at the inlet/outlet ports. In those cases, increasing the diameter and thickness allocated to microfluidic channels can ameliorate these issues, but the increased diameter and thickness of the microfluidic channels can make microfluidic cooling method detrimental to increased integration in the vertical direction. Therefore, for some vertical integration applications, microfluidic cooling can be simply too thick to be useful, or at the very least, it can be disadvantages as the three-dimensional systems scale up in the vertical direction.

### Thermal Management Via Immersion Cooling

Heat management for the 3D IC 10 can be provided by immersion cooling. The 3D IC 10 can be immersed in an electrically insulating coolant, such as a dielectric fluid. The dielectric coolant can function as a malleable heatsink, which can efficiently remove heat from the 3D IC 10. Immersion cooling can also make the packaging of the 3D IC 10 more simplified, as the 3D IC 10 immersed in a tank of dielectric coolant can be isolated from the environment, by easier means. However, the immersion cooling technique can still have the issue of lack of contact between the intermediate substrates of the 3D IC 10 and the dielectric coolant. Consequently, the substrates and layers of the 3D IC 10 can be manufactured with interlayer immersion cooling channels between the substrates to allow the dielectric coolant to reach the chip surface area between the substrates and cool the chips therein or thereon. For available dielectric coolants, a dedicated spacing of approximately 100-200 micrometers for immersion cooling channels can be used to provide efficient cooling. However, as with microfluidic chambers, the thickness of the interlayer immersion cooling channels can introduce an undesirable limitation in vertical integration and scaling of three-dimensional ICs.

### Thermal Management Via Vertical Cooling Channels

In one respect, many thermal management techniques use the horizontal spaces above or below the layers of the 3D IC 10 to remove heat from the surface areas of those layers, while preserving more of the horizontal surface area for the chips 32, interconnects and other active components. Heat sinks, microfluidic chambers and interlayer immersion cooling channels, provide cooling, without taking up space from the chip surface area 22, or with minimal interference with the surface area that can otherwise be used for the chips 32 or other active components of the 3D IC 10. In other words, it is desirable that a thermal management solution does not take away surface areas, which can otherwise be used for building active components, such as computing, memory, sensor components. Nonetheless, if a thermal management solution does not introduce substantial thickness to the layers, the loss in the chip surface area dedicated to thermal management can be compensated or counteracted by adding more layers in the vertical direction.

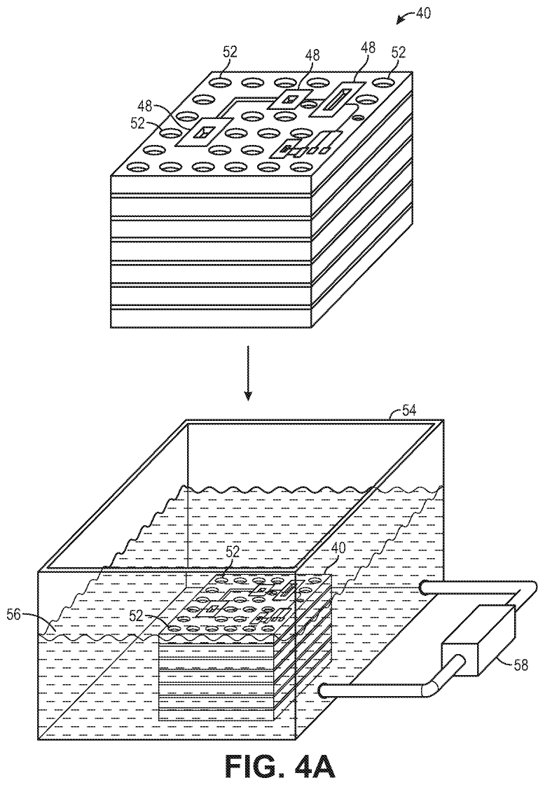

FIG. 3 illustrates a multilayered IC (MIC) 40 which includes vertical cooling channels that utilize the chip surface areas for cooling channels. For illustration purposes, MIC 40 is shown with three substrates or layers 42, 44, 46, vertically integrated in the A-B direction. However, fewer or more layers are possible. The layers 42, 44, and 46 can be similar in functionality, to the substrates 12, 16 and 18, as described in relation to FIGS. 1 and 2. The layers 42, 44 and 46 can include a chip surface area 50, which can be used to fabricate, assemble, mounted or otherwise build chips 48 in or within the layers 42-46. The chips 48 can be similar in functionality to chips 32 and can include any IC components, wiring, interconnect, energy storage, compute, memory, sensor or other functional chips as may be present in an integrated circuit. The chips 48 from one layer can be connected to the chips 48 on another layer by TSVs (not shown). Other interlayer connection methodologies can also be used. The layers 42, 44 and 46 are illustrated with spacing in between layers; however, this is not a requirement and the layers 42-46 can be made, without spacing or with minimal spacing between layers. The chip surface area 50 includes an active region, where the chips 48 and other components of MIC 40 are embedded. The chip surface area 50 also includes an inactive region, where no chip, interconnect, or other components are built. In other words, the inactive regions of the chip surface area 50 are analogous to the white space on a printed sheet of paper, and the chips 48 and other components of MIC 40 are analogous to the printed materials on the sheet of paper.

The inactive regions of the chip surface area 50 can be used for building vertical cooling channels 52 that traverse the vertical length of MIC 40 from the top surface of the top substrate to the bottom surface of the bottom substrate. Additionally, the volume between the substrates 42-46 includes an active volume, where chips 48, TSVs or other interconnect structures and other components of MIC 40 can be present providing electrical connection or functionality within and/or between the layers 42-46 and the chips 48. An inactive volume in MIC 40 includes all spaces and surfaces that do not include any components of MIC 40. The vertical cooling channels 52 can be built in the inactive volume in MIC 40 avoiding the active volume and structures and components therein.

Vertical cooling channels 52 traverse the volume of MIC 40 in the vertical A-B direction, without adding thickness to MIC 40 in the vertical direction A-B. Furthermore, they remove heat from MIC 40 in the horizontal C-D direction by using the same chip surface area 50 used by the chips 48 and other components of MIC 40. While some potential chip surface area 50 will be lost to the vertical cooling channels 52, the tradeoff in increased cooling efficiency can be desirable, as the resulting MIC 40 and the systems therein can perform more efficiently, due to the lower operational temperatures. As an example, allocating 50% of the chip surface area 50 to the inactive volume, where cooling channels 52 are fabricated, can result in drastically cooler operating temperatures for MIC 40. The loss of the chip surface area 50 to the vertical cooling channels 52 can be compensated by adding more layers to MIC 40 in the vertical direction A-B. Another advantage of designating inactive spaces and volumes within MIC 40 can result in layers with smaller chips 48 and fewer active components and connections in the active regions, leading to reduced manufacturing cost and complexity of MIC 40.

In some embodiments, the design of MIC 40 can include considerations of its thermal management solution and the presence of the vertical cooling channels 52. A design parameter, chip surface area density (CSAD), can be defined as the percentage of active areas of a substrate. In some embodiments, CSAD can be chosen, so the vertical cooling channels 52 built in the inactive surface areas can diffuse a heat flux density of approximately 1 kWatts/cm² or more per substrate. In some embodiments, the number of layers of MIC 40 can linearly increase in relation to CSAD. In some embodiments, CSAD can range from approximately 40%-90%.

The vertical cooling channels 52 pass through the outside layers of MIC 40, as well as through the intermediate layers of MIC 40, such as layer 44 or other intermediate layers (if more layers are used). Thus, unlike, cooling methods that have no contact or access to the intermediate layers, the vertical cooling channels 52 provide access and contact to heat generating elements of the intermediate layers of MIC 40. Additionally, since the vertical channels 52 integrate in the vertical A-B direction, using the inactive volume of MIC 40, layers 42-46 can be made as thin as other fabrication and processing parameters allow them to be.

When a fluid cooling medium is circulated in the vertical cooling channels 52, another advantage of the described vertical cooling channels 52, is that the pressure drop in each channel can be managed by choosing optimum diameters for vertical channels 52 in relation to the length of the vertical channels to avoid excessive pressure drop in each channel. In some implementations, the vertical length of MIC 40 in the A-B direction can be chosen, so the vertical channels 52 are of relatively short length. Consequently, the vertical cooling channels 52 can have less pressure drops by being in a network of many short-length vertical cooling channels 52, as opposed to, being a part of a network of a few long-length horizontal cooling channels (as may be the case in the horizontal cooling methodologies).

Furthermore, some horizontal cooling methodologies, such as horizontal microfluidic cooling can be inefficient when applied to WSI systems because of the excessive pressure drop the fluids can encounter when traversing the vast areas of the chips in such systems. Higher power-pumping of the coolant through microfluidic chambers can be a less attractive option in WSI systems because of reduced longevity, mechanical problems, sealant and leakage issues that can occur due to use of excessively high-pressured pumps and fluid circulation. This is an issue for vertically-integrated systems, as WSI systems can substantially contribute to vertical integration and scaling of more complex computing systems. Vertical cooling channels 52 can allow vertical integration and usage of WSI systems alone or in combination with other die assembly and fabrication systems, without encountering excessive pressure drop or requiring high-powered circulation pumps.

While the vertical cooling channels 52 are shown in FIG. 3, as cylinders through MIC 40, this is not a requirement. Other shapes of the vertical cooling channels 52 are also possible. Examples include vertical channels having variable diameters variable cross-sections, rectangular cross-sections, or other geometrically regular or irregular-shaped cross-sections. It is also possible that not all vertical cooling channels 52 extend perpendicularly down MIC 40, along the vertical direction A-B. In some embodiments, the vertical cooling channels 52 can start from a top surface of the top layer of MIC 40 and generally extend down in the vertical direction A-B (but not necessarily perpendicular to the horizontal C-D direction), avoiding active volume of MIC 40 and ending at an opening in the bottom surface of the bottom layer of MIC 40.

### Cooling Methods Using Vertical Cooling Channels

Various cooling methods can utilize the vertical cooling channels 52 to provide thermal management for MIC 40. Examples include, passive single or two-phase immersion cooling, active single or two-phase immersion cooling, microfluidic cooling, two-phase microfluidic cooling, spray cooling and impingement cooling.

### Single to Two-Phase Immersion Cooling

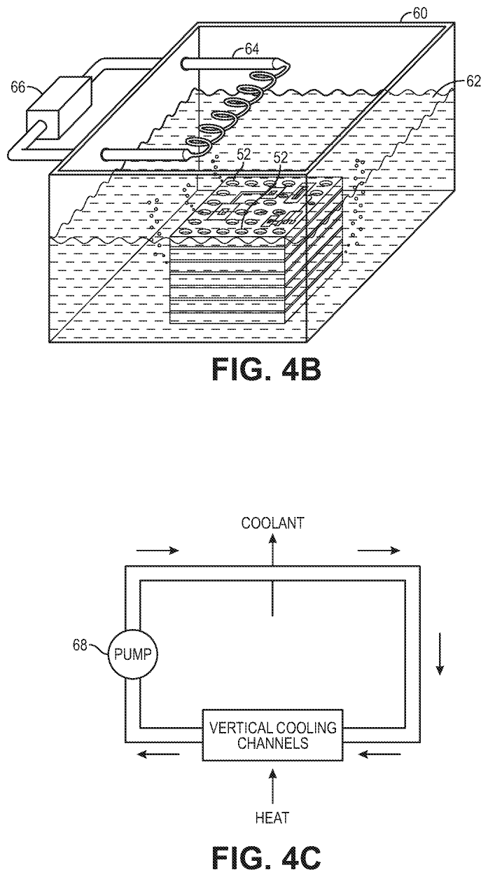

FIGS. 4A and 4B illustrate various immersion cooling techniques that can be employed in combination with the vertical cooling channels to provide thermal management for MIC 40. FIG. 4A illustrates a single-phase immersion cooling of MIC 40, where MIC 40 is immersed in a tank 54 of a single-phase dielectric coolant 56. The dielectric coolant 56 can include any single-phase dielectric fluid, such as mineral, synthetic or bio oils or fluorocarbons, which are chosen to not change phase for the range of temperatures encountered in the tank 54. The dielectric coolant 56 can be circulated and can exchange its heat to an environment via the heat exchanger 58. Single-phase immersion cooling in combination with the vertical cooling channels 52 can be an efficient, low cost and easy-to-implement cooling system to deploy for MIC 40.

FIG. 4B illustrates MIC 40 immersed in a tank 60 of a two-phase dielectric coolant 62. The dielectric coolant 62 can be a dielectric liquid with a low evaporation point (e.g., around 50° C.). Example dielectric coolants 62 can include hydrofluorocarbon families and other refrigerant families.

The dielectric coolant 62 can change phase (e.g., can turn from liquid form to gas form) as it absorbs heat from the vertical cooling channels 52 and other surfaces of MIC 40. The evaporated dielectric coolant 62 rises to the surface of the dielectric coolant 62 and reaches a condenser surface 64. A refrigeration unit 66 can maintain the temperature of the condenser surface 64 below a saturation temperature (evaporation temperature) of the dielectric coolant 62. The evaporated dielectric coolant 62 exchanges its absorbed heat with the condenser surface 64 and changes its phase back to the liquid form, dripping back to the dielectric coolant 62. The cycle continues and MIC 40 is cooled by phase changes of the dielectric coolant 62. In this configuration, the vertical cooling channels 52 provide access to intermediate layers of MIC 40 to the dielectric coolant 62, without adding to its thickness height in the vertical direction.

The single or two-phase immersion cooling of FIGS. 4A and 4B can also be deployed in combination with active components that introduce a velocity to the coolants 56 and 62 through the vertical cooling channels 52. FIG. 4C illustrates a diagram of active single-phase or two-phase immersion cooling, which in combination with vertical cooling channels, can provide thermal management to MIC 40. An active component, such as a pump 68, can introduce velocity to the coolants 56 or 62 to force them through the vertical cooling channels 52 with greater speed to improve cooling efficiency. The coolants 56 or 62 absorb heat from the chips, components and other active elements of MIC 40 as they traverse the vertical channels 52, and diffuse the heat into the remaining coolant 56 or 62.

### Microfluidic Cooling Via Vertical Cooling Channels

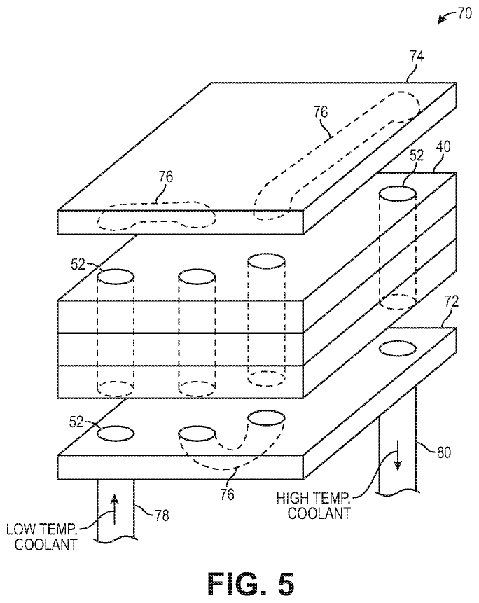

FIG. 5 illustrates a microfluidic cooling system (MCS) 70, which can be deployed with the vertical cooling channels 52 of MIC 40 to provide thermal management for MIC 40. The MCS 70 includes a bottom microfluidic substrate 72 and a top microfluidic substrate 74. The top and bottom microfluidic substrates 72 and 74 can include a plurality of complementary microfluidic channels 76 corresponding to the vertical cooling channels 52, in order to provide a continuous network of travel paths for a coolant to traverse the vertical cooling channels 52. A coolant can be injected into the continuous network of travel paths from inlet port 78 and collected from the outlet port 80. Having one pair of inlet/outlet ports is not mandatory, and in some implementations two or more inlet/outlet pairs may be used to reduce the length (and the pressure required) for the coolant to travel the vertical cooling channels 52. The coolant travels through one or more vertical cooling channels 52 and absorbs heat from active components of MIC 40. The heated coolant is collected in one or more outlet ports 80 and cooled via any method, including heat exchangers, radiators, condensers, refrigeration units, heat sinks, vents, fans and/or a combination of these and/or other cooling methodologies. The plurality of complementary microfluidic channels 76 embedded in the microfluidic substrates 72 and 74 allow the coolant to enter from an inlet port 78 into a vertical cooling channel 52 and exit into another vertical cooling channel 52, and continue to travel from one vertical cooling channel 52 to another until the coolant reaches an outlet port 80.

Both single and two-phase microfluidic cooling can be used. In single microfluidic cooling, the coolant does not change phase. Example single-phase coolants, which can be used include the single-phase coolants used in single-phase immersion cooling, as described above. However, the vertical cooling channels 52 and the top and bottom microfluidic substrates 72 and 74 can be electrically isolated from the active chips and components of MIC 40, thereby allowing using of electrically conductive coolants as well. In two-phase microfluidic cooling, the coolant or a portion thereof can change phase. The evaporated coolant, as well as the liquid coolant, can be collected at one or more outlet ports 80, where the coolant (evaporated and liquid) are cooled and returned to the inlet port 78 to continue the cooling cycle. Various material can be used for the coolant in the MCS 70. Both electrically conductive and electrically isolating coolants can be used. Examples include waters, oils and other coolant materials, as described above in relation to the embodiments of single-phase and two-phase immersion cooling techniques using vertical cooling channels, described above.

### Spray Cooling, Impingement Cooling

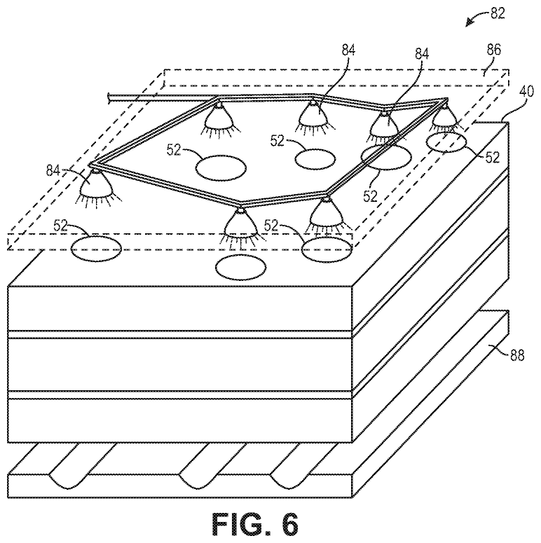

FIG. 6 illustrates a thermal solution system 82 utilizing spray cooling or impingement cooling in combination with vertical cooling channels 52. A network of nozzles 84 can be integrated in a cap substrate 86, where the output of each nozzle is directed to a vertical cooling channel 52. The Nozzles 84 can be configured to spray or jet impinge a coolant through the vertical cooling channels 52. A collection substrate 88 can catch and route the heated coolant and vapors away from MIC 40, where the heated coolant may be cooled through various cooling methods, such as heat exchangers, condensers, radiators, refrigeration units, heat sinks, vents, and/or a combination of these and/or other cooling methodologies. The coolant can be recycled and pumped through the nozzles 84 to repeat the cycle.

Combining Vertical Cooling Channels and Horizontal Cooling Methodologies

While the described vertical cooling channels address several challenges of the horizontal cooling methodologies, they can, nonetheless, be combined with those methods depending on the desired implementation. For example, in MIC 40, horizontally-integrated microfluidic channels can be implemented for only one or more “hot spot” intermediate substrates, while vertical cooling channels 52 can be used to provide thermal management to both hot spot substrates and other portions of MIC 40. Persons of ordinary skill in the art can envision various combinations of the disclosed techniques (including horizontal surface cooling and vertical cooling channels) to provide thermal management for multilevel ICs.

### Methods of Manufacturing Vertical Cooling Channels

The vertical cooling channels 52 can be manufactured by a variety of techniques. In one embodiment, laser micro-drilling can be used to build the vertical cooling channels 52. In another embodiment etching techniques, such as deep reactive-ion etching (DRIE) can be used. Referring to FIG. 3, the vertical cooling channels 52 can be built when the layers 42-46 are already stacked in the vertical direction A-B, or they can be built on the layers 42-46 before the layers are assembled and attached on one another vertically. Whether the vertical channels 52 are built before vertical assembly or after vertical assembly of the layers of MIC 40, 2D and 3D layout maps of inactive regions of MIC 40 can be used to determine where holes for vertical channels 52 can be built to avoid interfering with active components of MIC 40.

In one embodiment, active areas of a layer of MIC 40, such as chips, energy storage, wiring, power delivery lines, buses and all active components can be determined. The remaining areas of the layer can be used to build holes for vertical channels 52, using methods such as micro-drilling, etching or other techniques. The process can be repeated for other layers of MIC 40. When the layers of MIC 40 are assembled on top of one another, the vertical cooling channels 52 will be formed.

What is claimed is:

1. A system comprising:
a first substrate comprising a first plurality of chiplets and a first plurality of interconnects connecting two or more of the first plurality of chiplets, wherein the first substrate comprises a top surface;
a second substrate comprising a second plurality of chiplets and a second plurality of interconnects connecting two or more of the second plurality of chiplets, wherein the second substrate comprises a bottom surface, and wherein the first and second substrates are vertically stacked;
a plurality of through silicon vias (TSVs), connecting one or more of the first plurality of chiplets from the first substrate to one or more of the second plurality of the chiplets from the second substrate, wherein the first and second vertically-stacked substrates comprise an active volume comprising the chiplets, the interconnects and the TSVs, and remaining volume of the vertically-stacked first and second substrates comprise an inactive volume; and
a plurality of vertical cooling channels, formed in the inactive volume and extending from the top surface of the first substrate to the bottom surface of the second substrate.

2. The system of claim 1, wherein the chiplets comprise one or more of processor chips, memory chips, logic chips, and sensor chips.

3. The system of claim 1, further comprising a tank of single-phase dielectric coolant, wherein the vertically-stacked first and second substrates are immersed in the single-phase dielectric coolant.

4. The system of claim 3, further comprising a pump introducing velocity to the single-phase dielectric coolant entering the plurality of the vertical cooling channels.

5. The system of claim 1, further comprising a tank of two-phase dielectric coolant, wherein the vertically-stacked first and second substrates are immersed in the two-phase dielectric coolant.

6. The system of claim 5, further comprising a pump introducing velocity to the two-phase dielectric coolant entering the vertical cooling channels.

7. The system of claim 1, further comprising a top microfluidic substrate disposed on the top surface of the first substrate and a bottom microfluidic substrate disposed on the bottom surface of the second substrate, and wherein the top and bottom microfluidic substrates comprise complementary channels connecting two or more vertical cooling channels.

8. The system of claim 1, further comprising a cap substrate, wherein the cap substrate comprises a network of nozzles configured to spray a coolant into the vertical cooling channels.

9. The system of claim 1, wherein the active and inactive volumes are chosen such that the vertical cooling channels diffuse a heat flux density of greater than 1 kWatts/cm².

10. The system of claim 1, wherein the vertical cooling channels are formed via laser micro-drilling, etching or a combination of the two.

11. A method comprising:
forming, on a first substrate, a first plurality of chiplets and a first plurality of interconnects connecting two or more of the first plurality of chiplets, wherein the first substrate comprises a top surface;
forming, on a second substrate, a second plurality of chiplets and a second plurality of interconnects connecting two or more of the second plurality of chiplets, wherein the second substrate comprises a bottom surface;
vertically stacking the first and the second substrates;
connecting one or more of the first plurality of chiplets from the first substrate to one or more of the second plurality of the chiplets from the second substrate via a plurality of through silicon vias (TSVs), wherein the first and second vertically-stacked substrates comprise an active volume comprising the chiplets, the interconnects and the TSVs, and remaining volume of the vertically-stacked first and second substrates comprise an inactive volume; and
forming a plurality of vertical cooling channels in the inactive volume, wherein the vertical cooling channels extend from the top surface of the first substrate to the bottom surface of the second substrate.

12. The method of claim 11, wherein the chiplets comprise one or more of processor chips, memory chips, logic chips, and sensor chips.

13. The method of claim 11, further comprising immersing the vertically-stacked first and second substrates in a tank of single-phase dielectric coolant.

14. The method of claim 13, further comprising pumping the single-phase dielectric coolant through one or more of the plurality of the vertical cooling channels.

15. The method of claim 11, further comprising immersing the vertically-stacked first and second substrates in a tank of two-phase dielectric coolant.

16. The method of claim 15, further comprising pumping the two-phase dielectric coolant through one or more of the plurality of the vertical cooling channels.

17. The method of claim 11, further comprising:
forming a top microfluidic substrate on the top surface of the first substrate; and
forming a bottom microfluidic substrate on the bottom surface of the second substrate, wherein the top and bottom microfluidic substrates comprise complementary channels connecting two or more vertical cooling channels.

18. The method of claim 11, further comprising forming a cap substrate, wherein the cap substrate comprises a network of nozzles configured to spray a coolant into the vertical cooling channels.

19. The method of claim 11, wherein the active and inactive volumes are chosen such that the vertical cooling channels diffuse a heat flux density of greater than 1 kWatts/cm².

20. The method of claim 11, wherein forming the vertical cooling channels comprises laser micro-drilling, etching or a combination of the two.
